(19) United States
(12) Patent Application Publication
(10) Pub. No.: US 2010/0080905 A1
(43) Pub. Date: Apr. 1, 2010

(54) SOLUTE STABILIZATION OF SHEETS FORMED FROM A MELT

(75) Inventor: Frank SINCLAIR, Quincy, MA (US)

Correspondence Address: VARIAN SEMICONDUCTOR EQUIPMENT ASSC., INC., 35 DORY RD., GLOUCESTER, MA, 01930-2297, US

(73) Assignee: VARIAN SEMICONDUCTOR EQUIPMENT ASSOCIATES, INC., Gloucester, MA (US)

(21) Appl. No.: 12/566,197

(22) Filed: Sep. 24, 2009

Related U.S. Application Data
(60) Provisional application No. 61/101,186, filed on Sep. 30, 2008.

(51) Int. Cl. C23C 16/22; B22D 23/00; B22D 15/04; B28B 11/04

(52) U.S. Cl. 427/255.395; 164/47; 164/66.1; 164/371; 425/104; 427/255.6

(57) ABSTRACT

Embodiments of this apparatus and method introduce solutes into a sheet formed from a melt. A melt of a material is cooled and a sheet of the material is formed in the melt. A first fluid is introduced around the sheet at least partially while the sheet is formed. A second fluid also may be introduced. In one instance, use of the first fluid and second fluid may form a sheet that has two different solute concentrations.

### CROSS-REFERENCE TO RELATED APPLICATIONS

This application claims priority to the provisional patent application entitled “Solute Stabilization of Thin Sheets,” filed Sep. 30, 2008 and assigned U.S. App. No. 61/101,186, the disclosure of which is hereby incorporated by reference.

### FIELD

This invention relates to sheet formation from a melt and, more particularly, to introducing solutes into a sheet formed from a melt.

### BACKGROUND

Silicon wafers or sheets may be used in, for example, the integrated circuit or solar cell industry. Demand for solar cells continues to increase as the demand for renewable energy sources increases. There are two types of solar cells: silicon and thin film. The majority of solar cells are made from silicon wafers, such as single crystal silicon wafers. Currently, a major cost of a crystalline silicon solar cell is the wafer on which the solar cell is made. The efficiency of the solar cell, or the amount of power produced under standard illumination, is limited, in part, by the quality of this wafer. As the demand for solar cells increases, one goal of the solar cell industry is to lower the cost/power ratio. Any reduction in the cost of manufacturing a wafer without decreasing quality will lower the cost/power ratio and enable the wider availability of this clean energy technology.

The highest efficiency silicon solar cells may have an efficiency of greater than 20%. These are made using electronics-grade monocrystalline silicon wafers. Such wafers may be made by sawing thin slices from a monocrystalline silicon cylindrical boule grown using the Czochralski method. These slices may be less than 200 μm thick. To maintain single crystal growth, the boule must be grown slowly, such as less than 10 μm/s, from a crucible containing a melt. The subsequent sawing process leads to approximately 200 μm of kerf loss, or loss due to the width of a saw blade, per wafer. The cylindrical boule or wafer also may need to be squared off to make a square solar cell. Both the squaring and kerf losses lead to material waste and increased material costs. As solar cells become thinner, the percent of silicon waste per cut increases. Limits to ingot slicing technology may hinder the ability to obtain thinner solar cells.

Other solar cells are made using wafers sawed from polycrystalline silicon ingots. Polycrystalline silicon ingots may be grown faster than monocrystalline silicon. However, the quality of the resulting wafers is lower because there are more defects and grain boundaries and this lower quality results in lower efficiency solar cells. The sawing process for a polycrystalline silicon ingot is as inefficient as a monocrystalline silicon ingot or boule.

Another solution that may reduce silicon waste is cleaving a wafer from a silicon ingot after ion implantation. For example, hydrogen, helium, or other noble gas ions are implanted beneath the surface of the silicon ingot to form an implanted region. This is followed by a thermal, physical, or chemical treatment to cleave the wafer from the ingot along this implanted region. While cleaving through ion implantation can produce wafers without kerf losses, it has yet to be proven that this method can be employed to produce silicon wafers economically.

Yet another solution is to pull a thin ribbon of silicon vertically from a melt and then allow the pulled silicon to cool and solidify into a sheet. The pull rate of this method may be limited to less than approximately 18 mm/minute. The removed latent heat during cooling and solidifying of the silicon must be removed along the vertical ribbon. This results in a large temperature gradient along the ribbon. This temperature gradient stresses the crystalline silicon ribbon and may result in poor quality multi-grain silicon. The width and thickness of the ribbon also may be limited due to this temperature gradient. For example, the width may be limited to less than 80 mm and the thickness may be limited to 180 μm.

Horizontal ribbons of silicon that are physically pulled from a melt also have been tested. In one method, a seed attached to a rod is inserted into the melt and the rod and resulting sheet are pulled at a low angle over the edge of the crucible. The angle and surface tension are balanced to prevent the melt from spilling over the crucible. It is difficult, however, to initiate and control such a pulling process. Access must be given to the crucible and melt to insert the seed, which may result in heat loss. Additional heat may be added to the crucible to compensate for this heat loss. This additional heat may cause vertical temperature gradients in the melt that may cause non-laminar fluid flow. Also, a possibly difficult angle of inclination adjustment to balance gravity and surface tension of the meniscus formed at the crucible edge must be performed. Furthermore, since heat is being removed at the separation point of the sheet and melt, there is a sudden change between heat being removed as latent heat and heat being removed as sensible heat. This may cause a large temperature gradient along the ribbon at this separation point and may cause dislocations in the crystal. Dislocations and warping may occur due to these temperature gradients along the sheet.

Production of thin sheets separated horizontally from a melt, such as by using a spillway, has not been performed. Producing sheets horizontally from a melt by separation may be less expensive than silicon sliced from an ingot and may eliminate kerf loss or loss due to squaring. Sheets produced horizontally from a melt by separation also may be less expensive than silicon cleaved from an ingot using hydrogen ions or other pulled silicon ribbon methods. Furthermore, separating a sheet horizontally from a melt may improve the crystal quality of the sheet compared to pulled ribbons. A crystal growth method such as this that can reduce material costs would be a major enabling step to reduce the cost of silicon solar cells. However, a stabilized morphology or growth rate of the sheet may be needed to improve horizontal production of sheets. Accordingly, there is a need in the art for an improved method of sheet formation from a melt and, more particularly, a method of introducing solutes into a sheet formed from a melt.

### SUMMARY

According to a first aspect of the invention, a method is provided. The method comprises cooling a melt of a material. A sheet of the material is formed in the melt. A first fluid is introduced around the sheet at least partially during the forming and the sheet is transported.

According to a second aspect of the invention, an apparatus is provided. The apparatus comprises a vessel defining a channel configured to hold a melt of a material. A cooling plate is disposed proximate the melt. The cooling plate is configured to form a sheet of the material on the melt. A first fluid source is configured to introduce a first fluid around the sheet.

According to a third aspect of the invention, method is provided. The method comprises cooling a melt of a material. A first region of a sheet of the material is formed in the melt. The first region has a first solute concentration. A second region of the sheet of the material is formed in the melt while introducing a first fluid around the sheet at least partially during the forming of the second region. The second region has a second solute concentration higher than the first solute concentration.

### BRIEF DESCRIPTION OF THE DRAWINGS

For a better understanding of the present disclosure, reference is made to the accompanying drawings, which are incorporated herein by reference and in which:

FIG. 1 is a cross-sectional side view of an embodiment of an apparatus that separates a sheet from a melt;

FIG. 2 is a cross-sectional side view of an embodiment of an apparatus that pulls a sheet from a melt;

FIG. 3 is a cross-sectional side view of a first embodiment of sheet formation;

FIG. 4 is a cross-sectional side view of a second embodiment of sheet formation; and

FIG. 5 is a cross-sectional side view of an embodiment of sheet formation that uses melting.

### DETAILED DESCRIPTION

The embodiments of the apparatus and methods herein are described in connection with solar cells. However, these also may be used to produce, for example, integrated circuits, flat panels, or other substrates known to those skilled in the art. Furthermore, while the melt is described herein as being silicon, the melt may contain germanium, silicon and germanium, gallium, gallium nitride, other semiconductor materials, or other materials known to those skilled in the art. Thus, the invention is not limited to the specific embodiments described below.

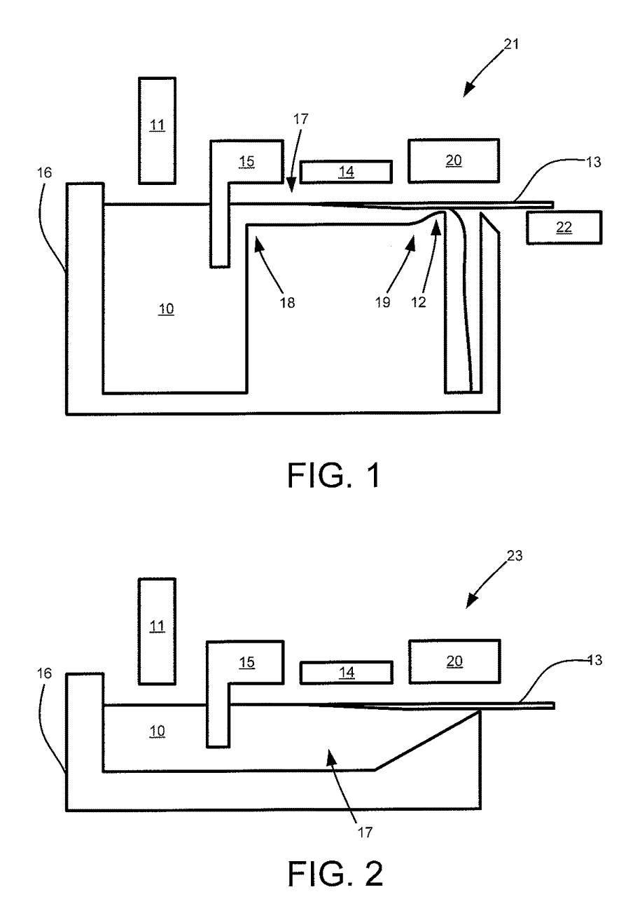

FIG. 1 is a cross-sectional side view of an embodiment of an apparatus that separates a sheet from a melt. The sheet-forming apparatus 21 has a vessel 16 and panels 15 and 20. The vessel 16 and panels 15 and 20 may be, for example, tungsten, boron nitride, aluminum nitride, molybdenum, graphite, silicon carbide, or quartz. The vessel 16 is configured to contain a melt 10. The melt 10 may be silicon. The melt 10 may be replenished through the feed 11 in one embodiment. The feed 11 may contain solid silicon. The melt 10 may be pumped into the vessel 16 in another embodiment. A sheet 13 will be formed on the melt 10. In one instance, the sheet 13 will at least partly float within the melt 10. While the sheet 13 is illustrated in FIG. 1 as floating in the melt 10, the sheet 13 may be at least partially submerged in the melt 10 or may float on top of the melt 10. In one instance, only 10% of the sheet 13 protrudes from above the top of the melt 10. The melt 10 may circulate within the apparatus 21.

This vessel 16 defines at least one channel 17. This channel 17 is configured to hold the melt 10 and the melt 10 flows from a first point 18 to a second point 19 of the channel 17. In one instance, the environment within the channel 17 is still to prevent ripples in the melt 10. The melt 10 may flow due to, for example, a pressure difference, gravity, a magnetohydrodynamic drive, a screw pump, an impeller pump, a wheel, or other methods of transport. The melt 10 then flows over the spillway 12. This spillway 12 may be a ramp, a weir, a small dam, or a corner and is not limited to the embodiment illustrated in FIG. 1. The spillway 12 may be any shape that allows a sheet 13 to be separated from the melt 10.

The panel 15 is configured in this particular embodiment to extend in part below the surface of the melt 10. This may prevent waves or ripples from disturbing the sheet 13 as it forms on the melt 10. These waves or ripples may form due to addition of melt material from the feed 11, pumping, or other causes known to those skilled in the art.

In one particular embodiment, the vessel 16 and panels 15 and 20 may be maintained at a temperature slightly above approximately 1687 K. For silicon, 1687 K represents the freezing temperature or interface temperature. By maintaining the temperature of the vessel 16 and panels 15 and 20 to slightly above the freezing temperature of the melt 10, the cooling plate 14 may function using radiation cooling to obtain the desired freezing rate of the sheet 13 on or in the melt 10. The cooling plate 14 in this particular embodiment is composed of a single segment or section but may include multiple segments or sections in another embodiment. The bottom of the channel 17 may be heated above the melting temperature of the melt 10 to create a small vertical temperature gradient in the melt 10 at the interface to prevent constitutional supercooling or the formation of dendrites, or branching projections, on the sheet 13. However, the vessel 16 and panels 15 and 20 may be any temperature above the melting temperature of the melt 10. This prevents the melt 10 from solidifying on the vessel 16 and panels 15 and 20.

The apparatus 21 may be maintained at a temperature slightly above the freezing temperature of the melt 10 by at least partially or totally enclosing the apparatus 21 within an enclosure. If the enclosure maintains the apparatus 21 at a temperature above the freezing temperature of the melt 10, the need to heat the apparatus 21 may be avoided or reduced and heaters in or around the enclosure may compensate for any heat loss. This enclosure may be isothermal with non-isotropic conductivity. In another particular embodiment, the heaters are not disposed on or in the enclosure and are rather in the apparatus 21. In one instance, different regions of the vessel 16 may be heated to different temperatures by imbedding heaters within the vessel 16 and using multi-zone temperature control.

The enclosure may control the environment where the apparatus 21 is disposed. In a specific embodiment, the enclosure contains an inert gas. This inert gas may be maintained at above the freezing temperature of the melt 10. The inert gas may reduce the addition of solutes into the melt 10 that may cause constitutional instabilities during the sheet 13 formation process.

The apparatus 21 includes a cooling plate 14. The cooling plate 14 allows heat extraction as the sheet 13 forms on the melt 10. The cooling plate 14 may cause the sheet 13 to freeze on or in the melt 10 when the temperature of the cooling plate 14 is lowered below the freezing temperature of the melt 10. This cooling plate 14 may use radiation cooling and may be fabricated of, for example, graphite, quartz, or silicon carbide. The cooling plate 14 may remove heat from the liquid melt 10 quickly, uniformly, and in controlled amounts. Disturbances to the melt 10 may be reduced while the sheet 13 forms to prevent imperfections in the sheet 13.

The heat extraction of the heat of fusion and heat from the melt 10 over the surface of the melt 10 may enable faster production of the sheet 13 compared to other ribbon pulling methods while maintaining a sheet 13 with low defect density. Cooling a sheet 13 on the surface of the melt 10 or a sheet 13 that floats on the melt 10 allows the latent heat of fusion to be removed slowly and over a large area while having a large sheet 13 extraction rate.

The dimensions of the cooling plate 14 may be increased, both in length and width. Increasing the length may allow a faster sheet 13 extraction rate for the same vertical growth rate and resulting sheet 13 thickness. Increasing the width of the cooling plate 14 may result in a wider sheet 13. Unlike the vertical sheet pulling method, there is no inherent physical limitation on the width of the sheet 13 produced using embodiments of the apparatus and method described in FIG. 1.

In one particular example, the melt 10 and sheet 13 flow at a rate of approximately 1 cm/s. The cooling plate 14 is approximately 20 cm in length and approximately 25 cm in width. A sheet 13 may be grown to approximately 100 μm in thickness in approximately 20 seconds. Thus, the sheet may grow in thickness at a rate of approximately 5 μm/s. A sheet 13 of approximately 100 μm in thickness may be produced at a rate of approximately 10 m²/hour.

Thermal gradients in the melt 10 may be minimized in one embodiment. This may allow the melt 10 flow to be steady and laminar. It also may allow the sheet 13 to be formed via radiation cooling using the cooling plate 14. A temperature difference of approximately 300 K between the cooling plate 14 and the melt 10 may form the sheet 13 on or in the melt 10 at a rate of approximately 7 μm/s in one particular instance.

The region of the channel 17 downstream from the cooling plate 14 and the under the panel 20 may be isothermal. This isothermal region may allow annealing of the sheet 13.

After the sheet 13 is formed on the melt 10, the sheet 13 is separated from the melt 10 using the spillway 12. The melt 10 flows from the first point 18 to the second point 19 of the channel 17. The sheet 13 will flow with the melt 10. This transport of the sheet 13 may be a continuous motion. In one instance, the sheet 13 may flow at approximately the same speed that the melt 10 flows. Thus, the sheet 13 may form and be transported while at rest with respect to the melt 10. The shape of the spillway 12 or orientation of the spillway 12 may be altered to change the velocity profile of the melt 10 or sheet 13.

The melt 10 is separated from the sheet 13 at the spillway 12. In one embodiment, the flow of the melt 10 transports the melt 10 over the spillway 12 and may, at least in part, transport the sheet 13 over the spillway 12. This may minimize or prevent breaking a single crystal sheet 13 because no external stress is applied to the sheet 13. The melt 10 will flow over the spillway 12 away from the sheet 13 in this particular embodiment. Cooling may not be applied at the spillway 12 to prevent thermal shock to the sheet 13. In one embodiment, the separation at the spillway 12 occurs in near-isothermal conditions.

The sheet 13 may be formed faster in the apparatus 21 than by being pulled normal to the melt because the melt 10 may flow at a speed configured to allow for proper cooling and crystallization of the sheet 13 on the melt 10. The sheet 13 will flow approximately as fast as the melt 10 flows. This reduces stress on the sheet 13. Pulling a ribbon normal to a melt is limited in speed because of the stresses placed on the ribbon due to the pulling. The sheet 13 in the apparatus 21 may lack any such pulling stresses in one embodiment. This may increase the quality of the sheet 13 and the production speed of the sheet 13.

The sheet 13 may tend to go straight beyond the spillway 12 in one embodiment. This sheet 13 may be supported after going over the spillway 12 in some instances to prevent breakage. A support device 22 is configured to support the sheet 13. The support device 22 may provide a gas pressure differential to support the sheet 13 using, for example, a gas or air blower. After the sheet 13 is separated from the melt 10, the temperature of the environment where the sheet 13 is located may slowly be changed. In one instance, the temperature is lowered as the sheet 13 moves farther from the spillway 12.

In one instance, the growth of the sheet 13, annealing of the sheet 13, and separation of the sheet 13 from the melt 10 using the spillway 12 may take place in an isothermal environment. The separation using the spillway 12 and the approximately equal flow rates of the sheet 13 and melt 10 minimize stress or mechanical strain on the sheet 13. This increases the possibility of producing a single crystal sheet 13.

In another embodiment, a magnetic field is applied to the melt 10 and sheet 13 in the sheet-forming apparatus 21. This may dampen oscillatory flows within the melt 10 and may improve crystallization of the sheet 13.

FIG. 2 is a cross-sectional side view of an embodiment of an apparatus that pulls a sheet from a melt. In this embodiment, the sheet-forming apparatus 23 transports the sheet 13 by pulling the sheet 13 from the melt 10. The melt 10 may not be circulating in a channel 17 in this embodiment and the sheet 13 may be pulled using a seed. A sheet 13 may be formed through cooling by the cooling plate 14 and the resulting sheet may be drawn out of the melt 10.

Both the embodiments of FIGS. 1-2 use a cooling plate 14. Different cooling temperatures across the length of the cooling plate 14, different flow rates of the melt 10 or pull speeds of the sheet 13, the length of the various sections of the sheet-forming apparatus 21 or sheet-forming apparatus 23, or the timing within the sheet-forming apparatus 21 or sheet-forming apparatus 23 may be used for process control. If the melt 10 is silicon, a polycrystalline sheet 13 or single crystal sheet 13 may be formed in the sheet-forming apparatus 21. In either the embodiment of FIG. 1 or FIG. 2, the sheet-forming apparatus 21 or sheet-forming apparatus 23 may be contained in an enclosure.

FIG. 1 and FIG. 2 are only two examples of sheet-forming apparatuses that can form sheets 13 from a melt 10. Other apparatuses or methods of vertical or horizontal sheet 13 growth are possible. While the embodiments of the methods and apparatuses described herein are specifically described with respect to the sheet-forming apparatus of FIG. 1, these embodiments may be applied to any vertical or horizontal sheet 13 growth method or apparatus. Thus, the embodiments described herein are not limited solely to the specific embodiments of FIGS. 1-2.

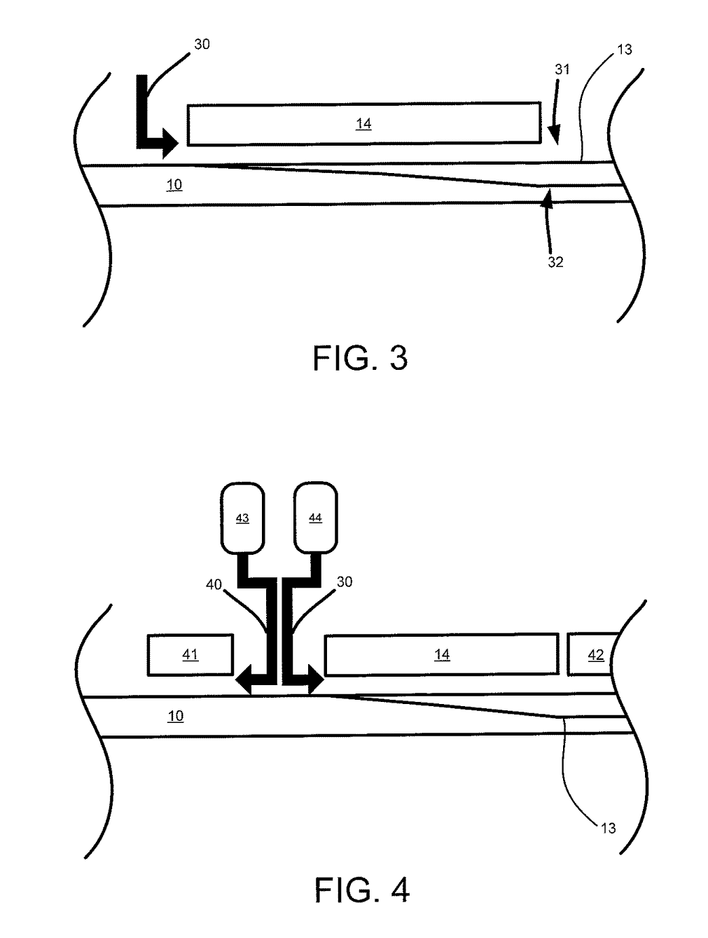

FIG. 3 is a cross-sectional side view of a first embodiment of sheet formation. The sheet 13 is formed in or on the melt 10 using the cooling plate 14. The melt 10 may be, for example, Si, Si and Ge, Ga, or GaN. A first fluid 30 is introduced around the sheet 13 at least partially during the formation of the sheet 13. The first fluid 30 may be, for example, POCl₃, AsH₃, B₂H₆, CH₄, C₂H₆, or CF₄. The first fluid 30 also may be another atom or compound that includes dopants or substitutional solutes such as P, As, B, C or other elements. The first fluid 30 may be a liquid or a gas. The first fluid 30 may be introduced, for example, around, adjacent to, or through the cooling plate 14.

The melting temperature (Tₘ) of the sheet 13 may be affected by any dissolved materials present in the crystal structure of the sheet 13. These dissolved materials may come from, for example, the first fluid 30. A solute concentration gradient in the sheet 13 will produce a Tₘ gradient where the Tₘ is higher in one region of the sheet 13 than the Tₘ in another region of the sheet 13. In one instance, the top 31 of the sheet 13 may be configured to have a higher Tₘ than the bottom 32 of the sheet 13 through addition of a solute, such as from the first fluid 30. This solute concentration gradient or difference in Tₘ from the top 31 to the bottom 32 of the sheet 13 may stabilize the morphology or growth rate of the sheet 13 produced using the cooling plate 14. Thus, a solute concentration gradient may enable a more stable fabrication of thinner sheets 13.

In the embodiment illustrated in FIG. 3, the first fluid 30 in contact with the top 31 of the sheet 13 will cause a region or portion of the sheet 13 to have a higher Tₘ. This region or portion may be a fraction of the sheet 13 or the entire sheet 13. The depth of the region or portion may be, for example, approximately 20 μm to 100 μm from the top 31 of the sheet 13 in one particular embodiment.

The introduction of the first fluid 30 may be configured to optimize the presence of the solute in the sheet 13. Forming a gradient of solute concentration in the melt 10 may be possible, but the diffusion rate of the solute may be high enough as to prevent prolonged existence of the gradient. Furthermore, diffusion rates of the solute into the sheet 13 from the melt 10 may be too slow to produce depths of solute of approximately 20 μm to approximately 100 μm in the sheet 13. Thus, timing the introduction of the first fluid 30 to allow diffusion of the solutes to the desired depth of the sheet 13 may need to be configured. To solve this problem, the first fluid 30 flowrate or introduction position may be adjusted.

FIG. 4 is a cross-sectional side view of a second embodiment of sheet formation. The sheet 13 is formed in or on the melt 10 using the cooling plate 14. The melt 10 may be, for example, Si, Si and Ge, Ga, or GaN. The first fluid 30, which may be a liquid or a gas, is introduced around the sheet 13 at least partially during the formation of the sheet 13. Panels 41 and 42 are disposed near the cooling plate 14. These panels 41 and 42 may be part of the cooling plate 14 or may correspond to panels 15 and 20 in FIGS. 1-2. The cooling plate 14 may be a single section or may be segmented into multiple sections. These multiple sections may operate at different temperatures. In this particular embodiment, the cooling plate 14 is a single section that operates at some temperature below Tₘ, which for silicon is approximately 1414° C. The panels 41 and 42 operate at some temperature above Tₘ. The first fluid 30 and second fluid 40 may be introduced upstream of or adjacent to the cooling plate 14 in this particular embodiment.

A second fluid 40, which may be a liquid or a gas, is introduced around the sheet 13 and melt 10. The second fluid 40 in one particular embodiment is an inert gas, such as a noble gas, or a reactive gas such as H₂, H₂O, Cl₂, or F₂ that leaches or getters the solute species from the surface of the sheet 13. The second fluid 40 is supplied from a second fluid source 43 and the first fluid 30 is supplied from a first fluid source 44. In one instance, the second fluid 40 is introduced at a temperature above Tₘ of the sheet 13 while the first fluid 30 is introduced at some temperature below Tₘ of the sheet 13, though other temperatures are possible. For example, both the second fluid 40 and first fluid 30 may be introduced at a temperature below Tₘ of the sheet 13 in another instance. The sheet 13 may flow or be pulled downstream from the cooling plate 14 after formation. As the sheet 13 remains in the melt 10 downstream of the cooling plate 14, the sheet 13 may be at least partly annealed or may change dimensions as the sheet 13 is thinned back into the melt 10.

The first fluid 30 and second fluid 40 are introduced using a differential gas flow. The second fluid 40 forms a gas curtain and may be directed in one direction. This gas curtain may be used to, for example, separate gases into different areas. This allows the first fluid 30 to preferentially flow in a different direction over the forming sheet 13.

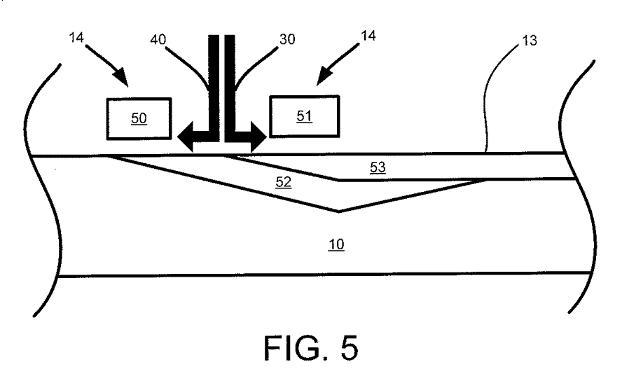

FIG. 5 is a cross-sectional side view of an embodiment of sheet formation that uses melting. The sheet 13 is formed in or on the melt 10 using the cooling plate 14. The melt 10 may be, for example, Si, Si and Ge, Ga, or GaN. The first fluid 30 and second fluid 40, which may be liquids or gases, are introduced around the sheet 13 at least partially during the formation of the sheet 13. The first fluid 30 may contain, for example, P, As, B, or C while the second fluid 40 may be an inert gas, such as a noble gas, or a reactive gas such as H₂, H₂O, Cl₂, or F₂ that leaches or getters the solute species from the surface of the sheet 13.

In this particular embodiment, the cooling plate 14 has multiple segments 50, 51 and the first fluid 30 and second fluid 40 are introduced through the cooling plate 14. The segments 50, 51 may operate at the same temperature or different temperatures below the Tₘ of the sheet 13.

The second fluid 40 forms a gas curtain for the first fluid 30. The first fluid 30 may flow in one direction while the second fluid 40 flows in a different direction due to this gas curtain. The second fluid 40 will flow over the sheet 13 while a first region 52 of the sheet 13 forms. This first region 52 has a first solute concentration. For example, the first solute concentration may be low or even zero. The first fluid 30 flows over the sheet 13 while a second region 53 of the sheet 13 forms. The second region 53 has a second solute concentration higher than the first solute concentration. The gas curtain of the second fluid 40 at least partly prevents the first fluid 30 from being directed over the sheet 13 while the first region 52 is formed.

As the sheet 13 is pulled or flows downstream of the cooling plate 14, the sheet 13 begins to melt back into or be thinned by the melt 10. This is because the melt 10 is at or above the Tₘ of the sheet 13. Thus, the thickness of the sheet 13 during formation by the cooling plate 14 may be different from the thickness of the sheet 13 after any melting or thinning. The presence of the solutes in the second region 53 due to the first fluid 30 will raise the Tₘ of the second region 53. Thus, a melting barrier is formed to prevent or impede this sort of thinning by the melt 10. The first region 52 of the sheet 13 may be melted or thinned, but the second region 53 may not be melted or thinned or may be melted or thinned less than the first region 52. This may improve the quality of the sheet 13 if the first region 52 has defects, uniformity problems, or dendrites. While melting or thinning using the melt 10 is specifically disclosed, the first region 52 also may be affected by heaters that perform melting or thinning of the sheet 13.

Furthermore, the second region 53 may be stabilized compared to the first region 52. Melting or thinning of the second region 53 may be made more uniform due to the presence of the solutes from the first fluid 30. This may reduce non-uniformities in the second region 53. The surfaces of the second region 53 or sheet 13 may be made more uniform or even through embodiments of the process described herein.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method comprising:
cooling a melt of a material;
forming a sheet of said material in said melt;
introducing a first fluid around said sheet at least partially during said forming; and
transporting said sheet.

2. The method of claim 1, wherein said material is selected from the group consisting of Si, Si and Ge, Ga, and GaN.

3. The method of claim 1, wherein said first fluid is selected from the group consisting of POCl₃, _{AsH}₃, ^{B}₂H₆, CH₄, C₂H₆, and CF₄.

4. The method of claim 1, wherein said first fluid contains an atom selected from the group consisting of P, As, B, and C.

5. The method of claim 1, wherein said first fluid is a gas.

6. The method of claim 1, further comprising separating said sheet from said melt using a spillway after said introducing of said first fluid.

7. The method of claim 1, further comprising introducing a second fluid around said sheet prior to said introducing of said first fluid around said sheet wherein said second fluid is selected from the group consisting of a noble gas, H₂, H₂O, Cl₂, and F₂.

8. An apparatus comprising:
a vessel defining a channel configured to hold a melt of a material;
a cooling plate disposed proximate said melt, said cooling plate configured to form a sheet of said material on said melt; and
a first fluid source configured to introduce a first fluid around said sheet.

9. The apparatus of claim 8, wherein said material is selected from the group consisting of Si, Si and Ge, Ga, and GaN.

10. The apparatus of claim 8, wherein said first fluid is a gas.

11. The apparatus of claim 8, further comprising a second fluid source configured to introduce a second fluid around said sheet, wherein said second fluid is selected from the group consisting of a noble gas, H₂, H₂O, Cl₂, and F₂.

12. The apparatus of claim 11, wherein said second fluid forms a gas curtain.

13. A method comprising:
cooling a melt of a material;
forming a first region of a sheet of said material in said melt, said first region having a first solute concentration; and
forming a second region of said sheet of said material in said melt while introducing a first fluid around said sheet at least partially during said forming of said second region, said second region having a second solute concentration higher than said first solute concentration.

14. The method of claim 13, wherein said material is selected from the group consisting of Si, Si and Ge, Ga, and GaN.

15. The method of claim 13, wherein said first fluid contains an atom selected from the group consisting of P, As, B, and C.

16. The method of claim 13, wherein said first fluid is a gas.

17. The method of claim 13, further comprising separating said sheet from said melt using a spillway after said forming of said second region of said sheet.

18. The method of claim 13, further comprising introducing a second fluid around said sheet at least partly during said forming of said first region, wherein said second fluid is selected from the group consisting of a noble gas, H₂, H₂O, Cl₂, and F₂.

19. The method of claim 13, further comprising melting said first region of said sheet after said forming of said second region.

20. The method of claim 19, wherein said melting is performed in said melt of said material.
